(19) United States
(12) Patent Application Publication
(10) Pub. No.: US 2010/0029050 A1
(43) Pub. Date: Feb. 4, 2010

(54) STRESS ENGINEERING FOR CAP LAYER INDUCED STRESS

(75) Inventors: VICTOR MOROZ, SARATOGA, CA (US); DIPANKAR PRAMANIK, SARATOGA, CA (US)

Correspondence Address: SYNOPSYS, INC. C/O HAYNES BEFFEL & WOLFELD LLP, P.O. BOX 366, HALF MOON BAY, CA, 94019, US

(73) Assignee: SYNOPSYS, INC., Mountain View, CA (US)

(21) Appl. No.: 12/577,017

(22) Filed: Oct. 9, 2009

Related U.S. Application Data
(62) Division of application No. 11/379,548, filed on Apr. 20, 2006.

(51) Int. Cl. H01L 21/336; G06F 17/50

(52) U.S. Cl. 438/197; 716/1; 257/E21.409

(57) ABSTRACT

Improved layouts take better advantage of desirable cap-layer induced transverse and vertical stress. In one aspect, roughly described, a tensile strained cap material overlies the transistor channels in the N-channel diffusion regions but not the P-channel diffusion regions. The material terminates at an edge that is located as far as practical from the N-channel diffusion, toward the P-channel diffusion. In another aspect, roughly described, a gate conductor crosses a P-channel diffusion region and terminates as far as practical beyond the edge without making undesirable electrical contact with any other features of the integrated circuit design, and without overlying any other diffusion regions. A compressively strained cap layer overlies the P-channel diffusion. In yet another aspect, roughly described, a gate conductor crosses an N-channel diffusion and extends by as short a distance as practical before terminating or turning. A tensile strained cap material overlies the N-channel diffusion.

### BACKGROUND

The invention relates to methods for improving integrated circuit performance through stress-engineering relative to a strained cap layer of the device, and articles manufactured thereby.

It has long been known that semiconductor materials such as silicon and germanium exhibit the piezoelectric effect (mechanical stress induced changes in electrical resistance). See for example C. S. Smith, “Piezoresistance effect in germanium and silicon”, Phys. Rev., vol. 94, pp. 42-49 (1954), incorporated by reference herein. The piezoelectric effect has formed the basis for certain kinds of pressure sensors and strain gauges, but only recently has it received attention in the manufacture of integrated circuits. In the manufacture of integrated circuits, stress tends to affect electron and hole mobility in the channel regions of transistors. Increased mobility results in increased on-current (Ion) and faster switching speeds, and conversely, decreased mobility results in decreased Ion and slower switching speeds. In particular, for N-channel transistors, it has been found greatly advantageous to reduce compressive stress (increase tensile stress) in the channel in the direction of current flow (referred to herein as the longitudinal direction). For P-channel transistors it has been found greatly advantageous to increase compressive stress (reduce tensile stress) in the channel in the longitudinal direction.

The stress in the channel regions of integrated circuit transistors can derive from many different sources, some of which can be manipulated to enhance or reduce stress as desired. One popular approach is based on uniaxial longitudinal stresses introduced by a strained cap layer. Commonly, after formation of the gate stacks, a contact etch stop layer (CESL), also called a cap layer, is applied over the wafer. This layer is frequently a nitride material, and is commonly available in pre-strained formulations with various compressive stresses of up to −2.5 GPa, and with various tensile stresses of up to +1.5 GPa. These residual strains couple into the transistor channel regions and can enhance or degrade transistor performance. In some fabrication processes, a tensile strained cap layer is deposited on the wafer, then etched away over the P-channel transistors. In other fabrication processes, a compressively strained cap layer is deposited on the wafer, then etched away over the N-channel transistors. In yet a third type of fabrication processes, a layer of one material type is applied first, etched away over one type of transistors, then a layer of the second material type is applied and etched away over the second type of transistors. The latter process is often referred to as DSL (dual stress liner). In all three types of processes, the interface between the two materials is typically half-way between the N-channel and P-channel diffusions, roughly coincident with the edges of the N-well and P-well implants, presumably because this permits the well implant masks to be re-used. The resulting cap layer thus is tensile over the N-channel transistors, or compressive over the P-channel transistors, or both. Assuming only longitudinal stress is considered, therefore, proper choice of cap layer materials can improve performance of both N-channel and P-channel transistors.

However, transistor performance is affected by stress in all three normal directions, not only the longitudinal direction. For example, compressive transverse stress coupled into transistor channel regions from strained cap layer materials can degrade performance of both N-channel and P-channel transistors, whereas tensile transverse stress can improve it. As another example, compressive vertical stress coupled into N-channel transistor channel regions from strained cap layer materials can improve performance.

The invention described herein provides methods and systems for improving integrated circuit layouts and fabrication processes in order to take better advantage of desirable cap-layer induced transverse and vertical stress, and to minimize undesirable cap-layer induced transverse and vertical stress. In one aspect of the invention, roughly described, a substrate carries N-channel and P-channel diffusion regions spaced apart transversely. A tensile strained cap material overlies the transistor channels in the N-channel diffusion region but not the P-channel diffusion region. But rather than terminating at an edge roughly half-way between the N- and P-channel diffusions, the tensile strained cap layer material terminates at an edge that is located as far as practical from the N-channel diffusion. This has the effect of decreasing the compressive effect that the tensile strained material has on the channel region of the N-channel diffusion transversely, thereby improving performance of the N-channel transistor. In addition, if a compressively strained cap material overlies the transistor channels in the P-channel diffusion region, then placing the interface between the two cap materials as far as practical from the N-channel diffusion also has the effect of increasing the tensile effect of the compressively strained material acting transversely on the channel of the P-channel diffusion, thereby improving performance of the P-channel transistor as well. In both cases, preferably the tensile strained cap material terminates between 0.75 and 1.0 times the distance from the N-channel diffusion region to the P-channel diffusion region. Even more preferably, it terminates at a distance from the P-channel diffusion region which is between 3 times σ and 5 times σ, where σ is the standard deviation of the misalignment probability distribution of the wafer stepper with which the wafer is positioned when exposing the photoresist for etching the tensile strained cap material.

In another aspect of the invention, roughly described, a substrate carries a P-channel diffusion region. A gate conductor crosses this diffusion region transversely and terminates beyond the edge without making electrical contact with any other features of the integrated circuit design, and without overlying any other diffusion regions that are part of the integrated circuit design. A compressively strained cap layer overlies the P-channel diffusion. The portion of the gate conductor extending transversely beyond the edge, instead of terminating as near as practical to the edge, is extended as far as practical beyond that edge. This has the effect of increasing the transverse tensile stress on the transistor channels in the P-channel diffusion, thereby improving performance of the P-channel transistors.

Preferably the gate conductor extends at least half the distance from the edge of the diffusion region to the next feature at which the gate conductor would affect the circuit design. Even more preferably the gate conductor terminates at a position that is between three times σ and five times σ short of the next feature, where σ is the standard deviation of the misalignment probability distribution of the wafer stepper with which the wafer is positioned when exposing the photoresist for etching the gate conductor layer.

In yet another aspect of the invention, roughly described, a substrate carries an N-channel diffusion region. A gate conductor crosses this diffusion region and extends transversely beyond the edge of the diffusion region. A tensile strained cap material overlies at least a portion of the gate conductor and extends transversely beyond the edge of the diffusion region. The gate conductor, instead of terminating or turning at a safe or convenient distance beyond the edge of the N-channel diffusion, terminates or turns as nearly as practical to that edge. This has the effect of reducing the transverse compressive stress on the transistor channels in the N-channel diffusion, thereby improving performance of the N-channel transistors. In addition, a tensile strained cap material tends to apply compressive stress vertically, at positions on the substrate laterally surrounding the gate stack. By terminating or turning the gate stack as nearly as practical to the edge of the N-channel diffusion, the compressive stress that the cap layer applies vertically beyond the termination or turn of the gate stack is closer to the channel and thus more greatly enhances the vertical compressive stress in the channel. Greater vertical compressive stress in the channel of the N-channel transistor will improve performance of the transistor.

Preferably the gate conductor terminates or turns at a position that is between three times σ and five times σ transversely beyond the edge of the N-channel diffusion, where σ is the standard deviation of the misalignment probability distribution of the wafer stepper with which the wafer is positioned when exposing the photoresist for etching the gate conductor layer.

### BRIEF DESCRIPTION OF THE DRAWINGS

FIG. 1 is a simplified representation of an illustrative digital integrated circuit design flow incorporating features of the invention.

FIG. 2 illustrates a high level layout organization for a region of an integrated circuit that may incorporate features of the invention.

FIG. 3 illustrates a plan view of a typical layout region of FIG. 2.

FIG. 4 is a cross-sectional view of a portion of FIG. 3, taken along sight lines A-A of FIG. 3.

FIG. 5 is a plan view of a layout region implementing features of the invention.

FIG. 6 is a cross-sectional view of a portion of FIG. 5, taken along sight lines A-A of FIG. 5.

FIG. 7 is a cross-section of a portion of the layout of FIG. 4.

FIG. 8 is an overall flowchart of an integrated circuit fabrication process incorporating features of the invention.

FIG. 9 is a simplified block diagram of a computer system that can be used to implement features of the invention.

### DETAILED DESCRIPTION

The following description is presented to enable any person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the spirit and scope of the present invention. Thus, the present invention is not intended to be limited to the embodiments shown, but is to be accorded the widest scope consistent with the principles and features disclosed herein.

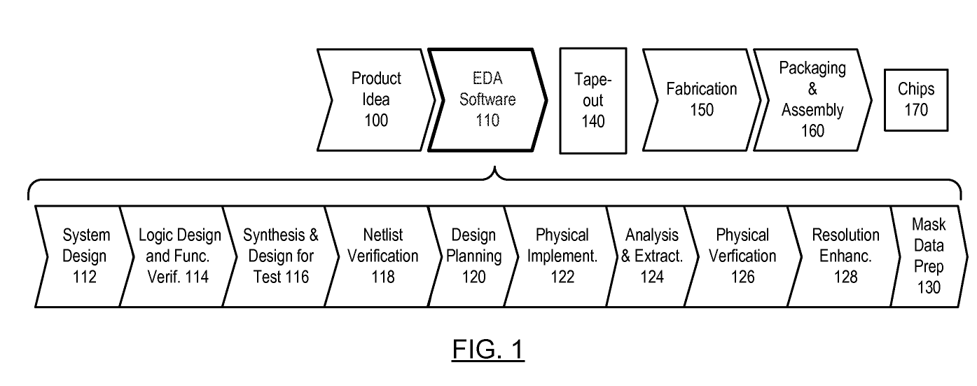

FIG. 1 shows a simplified representation of an illustrative digital integrated circuit design flow. At a high level, the process starts with the product idea (step 100) and is realized in an EDA (Electronic Design Automation) software design process (step 110). When the design is finalized, it can be taped-out (step 140). After tape out, the fabrication process (step 150) and packaging and assembly processes (step 160) occur resulting, ultimately, in finished integrated circuit chips (result 170).

The EDA software design process (step 110) is actually composed of a number of steps 112-130, shown in linear fashion for simplicity. In an actual integrated circuit design process, the particular design might have to go back through steps until certain tests are passed. Similarly, in any actual design process, these steps may occur in different orders and combinations. This description is therefore provided by way of context and general explanation rather than as a specific, or recommended, design flow for a particular integrated circuit.

A brief description of the components steps of the EDA software design process (step 110) will now be provided.

System design (step 112): The designers describe the functionality that they want to implement, they can perform what-if planning to refine functionality, check costs, etc. Hardware-software architecture partitioning can occur at this stage. Example EDA software products from Synopsys, Inc. that can be used at this step include Model Architect, Saber, System Studio, and DesignWare® products.

Logic design and functional verification (step 114): At this stage, the VHDL or Verilog code for modules in the system is written and the design is checked for functional accuracy. More specifically, the design is checked to ensure that produces the correct outputs in response to particular input stimuli. Example EDA software products from Synopsys, Inc. that can be used at this step include VCS, VERA, DesignWare®, Magellan, Formality, ESP and LEDA products.

Synthesis and design for test (step 116): Here, the VHDL/Verilog is translated to a netlist. The netlist can be optimized for the target technology. Additionally, the design and implementation of tests to permit checking of the finished chip occurs. Example EDA software products from Synopsys, Inc. that can be used at this step include Design Compiler®, Physical Compiler, Test Compiler, Power Compiler, FPGA Compiler, Tetramax, and DesignWare® products.

Netlist verification (step 118): At this step, the netlist is checked for compliance with timing constraints and for correspondence with the VHDL/Verilog source code. Example EDA software products from Synopsys, Inc. that can be used at this step include Formality, PrimeTime, and VCS products.

Design planning (step 120): Here, an overall floor plan for the chip is constructed and analyzed for timing and top-level routing. Example EDA software products from Synopsys, Inc. that can be used at this step include Astro and IC Compiler products.

Physical implementation (step 122): The placement (positioning of circuit elements) and routing (connection of the same) occurs at this step. Example EDA software products from Synopsys, Inc. that can be used at this step include the Astro and IC Compiler products. Certain aspects of the inventions herein can take place during this step.

Analysis and extraction (step 124): At this step, the circuit function is verified at a transistor level, this in turn permits what-if refinement. Example EDA software products from Synopsys, Inc. that can be used at this step include AstroRail, PrimeRail, Primetime, and Star RC/XT products.

Physical verification (step 126): At this step various checking functions are performed to ensure correctness for: manufacturing, electrical issues, lithographic issues, and circuitry. Example EDA software products from Synopsys, Inc. that can be used at this step include the Hercules product.

Resolution enhancement (step 128): This step involves geometric manipulations of the layout to improve manufacturability of the design. Example EDA software products from Synopsys, Inc. that can be used at this step include Proteus, ProteusAF, and PSMGen products.

Mask data preparation (step 130): This step provides the “tape-out” data for production of masks for lithographic use to produce finished chips. Example EDA software products from Synopsys, Inc. that can be used at this step include the CATS® family of products.

As used herein, an “integrated circuit design” is a transistor level design, after synthesis from VHDL and before layout. A designer can “specify” an integrated circuit design either by specifying it at the transistor level, or by specifying at a higher level and manually or automatically converting it to the transistor level through one or more sub-steps.

As used herein, a “layout” defines a set of masks that, when applied in a fabrication process, together define the physical features of the integrated circuit device. Among other things, these features can include transistor source, drain and channel regions, and diffusion regions, and STI regions, and so on, and together these features define circuit and non-circuit structures such as the transistors specified in the integrated circuit design. The masks defined by a “layout”, as that term is used herein, may (and typically do) go through one or more post-processing steps such as steps 126-130 (FIG. 1) before they are finalized for production. Note that some features are sometimes present on an integrated circuit chip for non-circuit reasons. An example is dummy diffusion regions, which might exist only for purposes of stress relief or for promoting CMP uniformity. Dummy diffusions are not considered herein to be part of the circuit design.

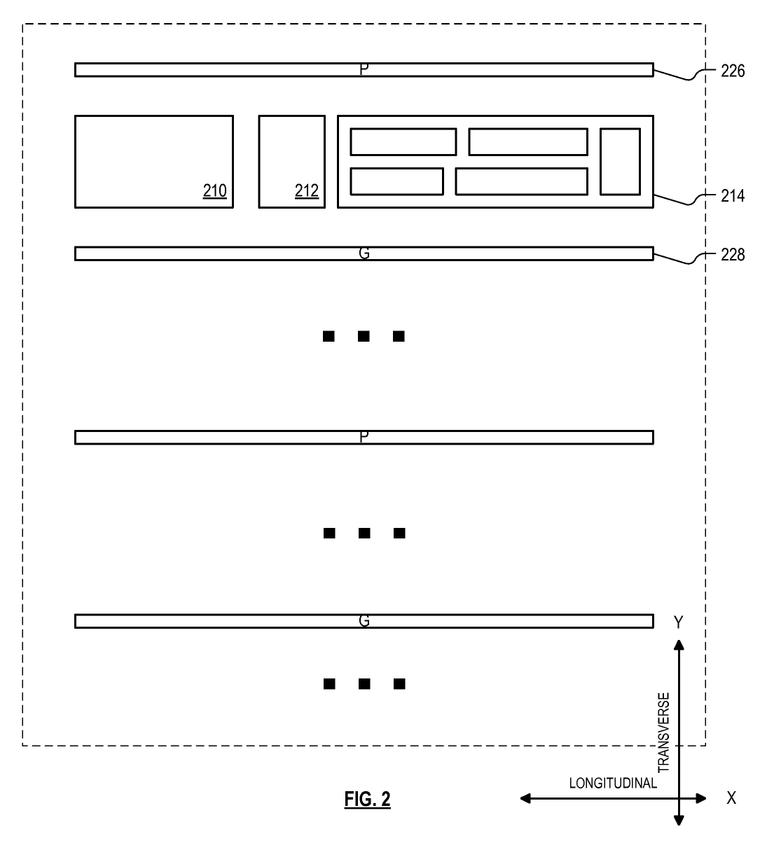

FIG. 2 illustrates a common high level layout organization for a region of an integrated circuit. As shown in FIG. 2, this layout includes power supply rails (conductors) that extend across most or all of the chip in the X dimension. Such an arrangement is common, especially but not exclusively for ASICs, standard cells and FPGAs. The layout includes power supply conductors 226 and 228, which in typical 2-voltage circuits (power and ground), alternate power and ground in the Y dimension. The transistors of the logic circuitry are laid out in a strip between a pair of the rails, usually within individual cells or macrocells such as 210, 212 and 214 in FIG. 2. Typically the cells are all of the same size in the Y dimension but may vary in size in the X dimension. Cell 214, for example, represents N-channel and P-channel diffusion regions as the smaller rectangles, and the regions between the rails and outside of the diffusion regions are shallow trench isolation (STI) regions containing oxide. As with all drawings herein, the drawing of FIG. 2 is not to scale.

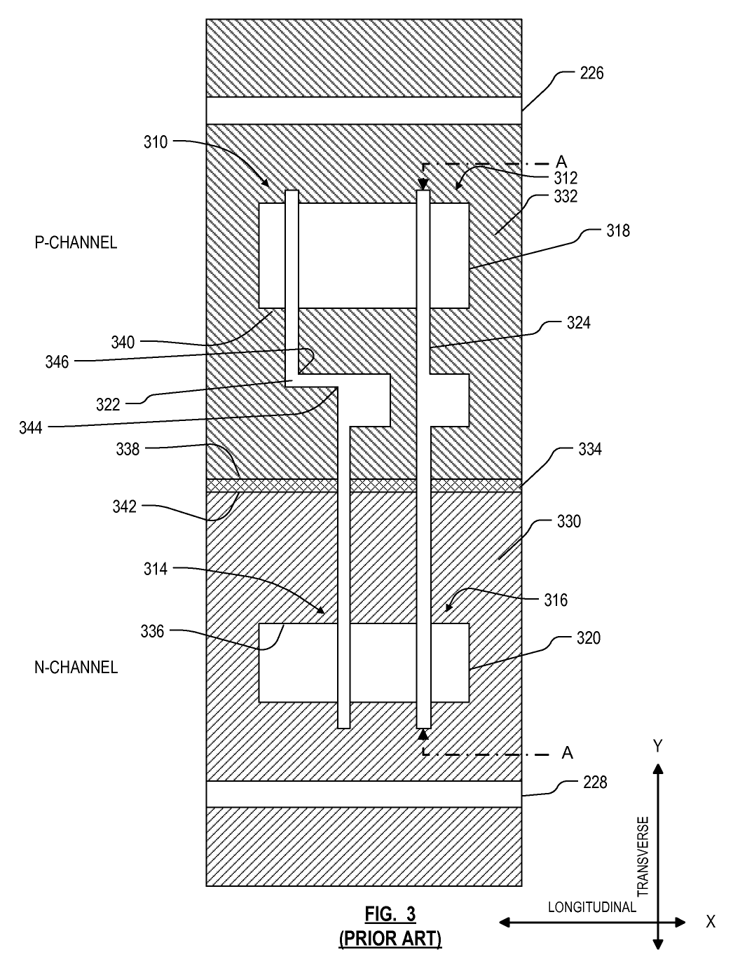

FIG. 3 illustrates a plan view of a typical layout region such as 212 (FIG. 2). Shown in FIG. 3 are two P-channel transistors 310 and 312, and two N-channel transistors 314 and 316. The two P-channel transistors share a diffusion region 318, and the two N-channel transistors share a different diffusion region 320. Each transistor has a channel which is defined by its diffusion region and a gate conductor which crosses the diffusion region. The drain and source regions of each of the transistors are the portions of the diffusion regions on opposite sides of the gate conductor, but whether one constitutes the source and the other the drain or vice-versa, depends on the circuit being implemented.

In typical CMOS fashion, to form a logical inverter element, the gate conductor crosses both a P-diffusion and an N-diffusion to define both a P-channel and an N-channel transistor. Thus in FIG. 3 a gate conductor 322 crosses both diffusion regions to define both transistors 310 and 314, and a gate conductor 324 crosses both diffusion regions to define both transistors 312 and 316. Gate conductor 324 is straight, but gate conductor 322 makes two turns 344 and 346 between the two diffusion regions 318 and 320. The turns are located at a comfortable distance from both diffusion regions.

The channels of the transistors in a typical fabrication process are slightly different (from left-to-right in the figure) than the gate conductors themselves because of the addition of other components of the gate stack (not shown in FIG. 3) such as spacers, and lateral diffusion of the source and drain dopants under the gate. As used herein, the term “region” represents a two-dimensional area in a plan view of the layout. Stress “in” a region is considered to be the stress close to the surface of the region, where current flows. In the embodiments described herein, an approximation is made that the stress “in” a region is equal to the stress “at” the surface of the region. In another embodiment, stresses within a volume of the chip can be taken into account as well, including at depths below the surface.

As used herein and as shown in FIG. 3, the “longitudinal” direction of a transistor is the direction of current flow between source and drain when the transistor is turned on. The “transverse” direction is perpendicular to the longitudinal direction, and perpendicular to the direction of current flow. Both the longitudinal and transverse directions of the transistor are considered to be “lateral” directions, meaning a direction that is parallel to the surface. Other “lateral” directions include those (not shown) which are parallel to the surface but intersect both the transverse and longitudinal directions at angles. The “vertical” direction is normal to the surface of the channel and therefore perpendicular to all possible lateral directions. The “length” of a structure in the layout is its length in the longitudinal direction, and its “width” is its width in the transverse direction. It can be seen from the layout of FIG. 3 that the channel lengths are significantly shorter than their widths, which is typical for the transistors that are used in logic circuits. Also shown in FIG. 3 are X and Y coordinate axes of the layout. Primarily for lithographic reasons, it is common in logic circuit design that all transistors be oriented alike, and consistent with this convention, in the layout of FIG. 3, all four transistors are oriented such that the longitudinal direction of the transistors are in the X direction of the layout, and the transverse direction of the transistors are in the Y direction of the layout. The Z direction, not visible in FIG. 3, is perpendicular to both the X and Y directions, representing a depth into the integrated circuit chip.

Additionally, the term “region”, as used herein, does not necessarily imply a physical boundary. That is, one “region” can contain multiple “sub-regions”, which themselves are considered herein to be “regions” as well. Thus it is reasonable to refer to a region within a diffusion region, even one that has not been defined physically in any way. In FIG. 3, more than one set of source and drain diffusion regions share a single overall diffusion region. In another embodiment, the source, drain and channel regions collectively are laterally co-extensive with the overall diffusion region. Also, in another embodiment, some of the source and drain diffusion regions might be made of different materials (e.g. SiGe) than the channel region (e.g. Si). In all of these cases it can be said that the source diffusion region forms “at least part of” a diffusion region, that the drain diffusion region forms “at least part of” a diffusion region, and that a channel region can exist even before it is defined physically.

FIG. 3 also illustrates power and ground buses 226 and 228, respectively. Typically these buses include one or more metal layers overlying one or more polysilicon layers, which in turn overly diffusions in the silicon substrate. At least one of the polysilicon layers in the power and ground buses 226 and 228 is the same layer as a polysilicon layer in the gate conductors 322 and 324.

Region 330 in FIG. 3 is a tensile strained silicon nitride cap layer overlying the N-channel diffusion region 320, the power supply bus 228, and a portion of each of the two gate conductors 322 and 324. Similarly, region 332 is a compressively strained silicon nitride cap layer overlying the P-channel diffusion region 318, the power supply bus 226, and a portion of each of the two gate conductors 322 and 324. As used herein, layers which are termed “above” or “below” other layers, can in various embodiments be separated from such other layers by one or more intervening layers. If no intervening layer is intended, then the terms “immediately above” or “immediately below” are used herein. The same interpretation is intended for layers being described as “superposing”, “underlying” or “overlying” another layer. In addition, as used herein, a layer that overlies a particular region of an underlying layer is also considered to overly each sub-region within the particular region in the underlying layer. Accordingly, the cap layers 330 and 332, which overly the diffusions 320 and 318, respectively, also overly the channel regions of the transistors in the diffusions 320 and 318, respectively.

The tensile strained cap layer material in region 330 extends transversely from an edge 336 of the N-channel diffusion region 320 toward the P-channel diffusion region 318. (It also extends transversely in the opposite direction from edge 336, as well as extending longitudinally). In the transverse dimension, the tensile strained cap layer material terminates at an edge 338 which is located at approximately half the transverse distance from the N-channel diffusion region 320 to the P-channel diffusion region 318. This is in accord with conventional practice: since the termination of the material in the transverse dimension is conventionally considered non-critical, it is commonplace to locate the termination edge at approximately the half-way distance between the two diffusions. This enables the mask used to expose the photoresist for etching the tensile strained cap layer material, to be the same as the mask used to expose the photoresist for a well implant, thereby avoiding the need to create an additional mask.

Similarly, the compressively strained cap layer material in region 332 extends transversely from an edge 340 of the N-channel diffusion region 320 toward the N-channel diffusion region 320. (It also extends transversely in the opposite direction from edge 340, as well as extending longitudinally). In the transverse dimension, the compressively strained cap layer material terminates at an edge 342 which is located at approximately half the transverse distance from the P-channel diffusion region 318 to the P-channel diffusion region 320. Again, this is in accord with conventional practice: since it enables the mask used to expose the photoresist for etching the compressively strained cap layer material, to be the same as the mask used to expose the photoresist for a well implant.

The edges at which the two cap layer materials terminate in FIG. 3 substantially coincide with each other. The term “substantially” here is intended to accommodate either a slight spacing between the two edges or a slight overlap, both typically due to either mask misalignment or a designer's overcompensation to protect against mask misalignment. In the embodiment of FIG. 3, the compressively strained silicon nitride cap layer material in region 332 overlaps the tensile strained silicon nitride cap layer material in region 330 by a slight amount in an overlap region 334.

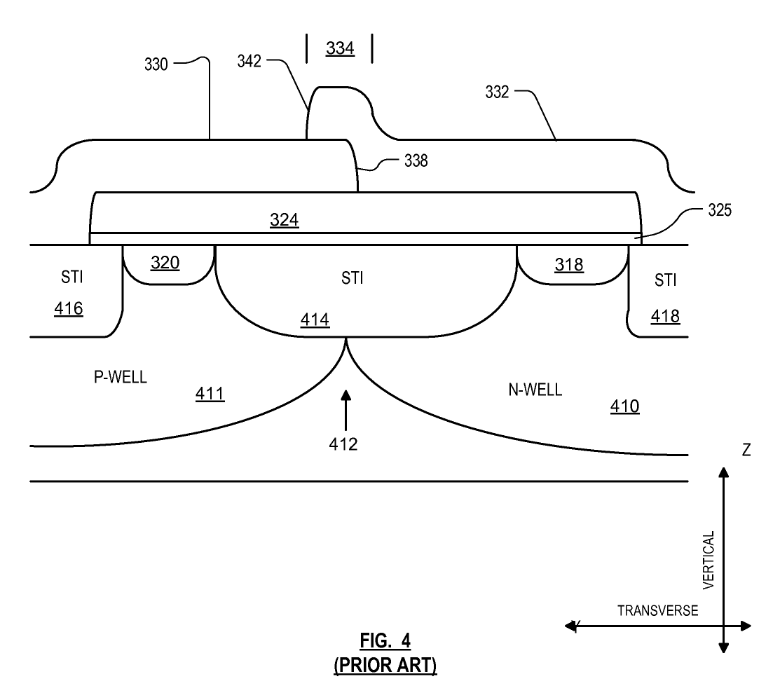

FIG. 4 is a cross-sectional view of a portion of FIG. 3, taken along sight lines A-A of FIG. 3. In addition to showing the diffusion regions 320 and 318 and the polysilicon gate conductor 324, FIG. 4 also shows the gate dielectric layer 324 below the gate conductor 324. FIG. 4 also shows an N-well 410 below the P-channel diffusion 318, and a P-well 411 below the N-channel diffusion 320. In the transverse dimension, the two wells terminate and meet each other roughly at a common edge 412 that is about half-way between the N-diffusion 320 and the P-diffusion 318. FIG. 4 also shows STI region 414 between the two diffusions 318 and 320, STI region 416 on the opposite side of N-channel diffusion 320 transversely from STI region 414, and STI region 418 on the opposite side of P-channel diffusion 318 transversely from STI region 414. FIG. 4 also shows the tensile strained cap layer material 330 extending transversely about half way to the P-channel diffusion 318, terminating at edge 338 roughly coinciding with the common edge of the N-well 410 and P-well 411. Similarly, FIG. 4 also shows the compressively strained cap layer material 332 extending transversely about half way to the N-channel diffusion 320, terminating at edge 342 also roughly coinciding with the common edge of the N-well 410 and P-well 411. The compressively strained cap layer material 332 overlaps the tensile strained cap layer material 330 by distance 334, but as previously mentioned, the two materials are still considered herein to terminate at substantially the same edge. As used herein, the substrate may be said to “carry” all of the components illustrated in FIG. 4, including the wells, diffusions, STI regions, gate dielectric layers, gate conductors and strained cap layer materials. The term “carrying” is not intended herein to distinguish between substances disposed in the substrate body itself, or disposed in an overlying layer.

It has been determined that a number of simple layout modifications can substantially improve the performance of both N-channel and P-channel transistors due to transverse and vertical stress components coupled into the channel regions from the strained cap layers. First, it is noted that on an integrated circuit in which a tensile strained cap layer covers virtually the entire chip, very little transverse stress, compressive or tensile, is coupled into the N-channel regions transversely. But in an arrangement such as that of FIGS. 3 and 4, the tensile strained cap layer material 330 terminates in the transverse direction reasonably near to the N-channel transistors. This effectively “releases” the cap layer material, permitting it to shrink more in the transverse direction. This tendency to shrink tends to couple compressive stress transversely into the channels of the N-channel transistors in N-channel diffusion 320, which degrades performance. Accordingly, it has been determined that as long as a tensile cap layer material is to terminate transversely and thereby release it to apply such compressive stress, it would be advantageous to locate the termination edge as far as practical from the N-channel diffusion. The compressive transverse stress coupled into the N-channels will therefore be reduced, and N-channel transistor performance thereby improved.

In an embodiment in which a compressively strained cap layer material 332 is applied over the P-channel diffusion 318, repositioning the edge between the two cap layer materials to a position as close as practical to the P-channel diffusion has the additional advantage of releasing the compressively strained material over the P-channels to expand and thereby couple beneficial tensile stress transversely into the P-channels. Accordingly, both considerations render it advantageous to relocate the edge to a position as far as practical from the N-channel diffusion and as near as practical to the P-channel diffusion.

Second, in the case of a gate conductor crossing a P-channel diffusion and extending transversely beyond the edge, it has been determined that the greater the distance by which the gate conductor extends beyond the edge, the greater the tensile stress that the compressively strained cap layer material couples into the P-channels transversely. Accordingly, since transverse tensile stress is beneficial, it has been determined that a gate conductor crossing a P-channel diffusion should extend beyond the edge thereof by as far as practical.

Third, in the case of a gate conductor crossing an N-channel diffusion and extending transversely beyond the edge, it has been determined that the greater the distance by which the gate conductor extends beyond the edge, the greater the compressive stress that the tensile strained cap layer material couples into the N-channels transversely. Accordingly, since transverse compressive stress is detrimental, it has been determined that a gate conductor crossing an N-channel diffusion should terminate or bend as nearly as practical beyond the edge of the N-channel diffusion.

It has also been determined that the greater the number of vertical surfaces that surround the gate conductor near the channel of an N-channel transistor, the greater the compressive stress coupled into the channel vertically. Where a gate conductor crosses an N-channel diffusion and extends significantly beyond it, only the long vertical surfaces of the gate conductor (the vertical surfaces whose long dimension is transverse), are available to couple compressive vertical stress. Accordingly, since vertical compressive stress is beneficial to the performance of N-channel transistors, it has been determined that these gate conductors should terminate or turn as near as practical to the diffusion boundary so as to provide an additional surface—the termination surface of the gate conductor—along which the cap layer can couple compressive stress into the channel vertically.

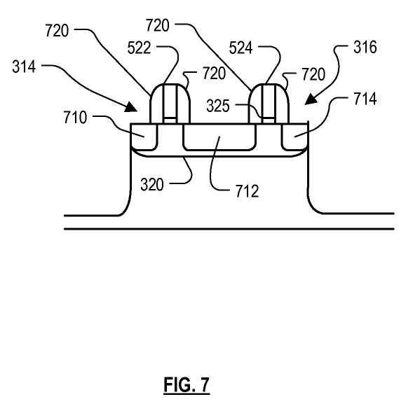

FIG. 7 illustrates a cross-section of the two N-channel transistors 314 and 316 shown in FIG. 4. The shared diffusion region 320 is shown, as are source and drain regions 710, 712 and 714. The gate conductors 522 and 524 and their underlying gate dielectric layers are also shown. In a typical embodiment, gate conductors are formed of one or more conductive materials such as polysilicon, and in a typical embodiment, spacer material 720 borders the gate conductor itself. Additional layers, not shown in FIG. 7, also may overly the gate conductors before the cap layer is applied. The gate conductor and the various materials surrounding and overlying it, and patterned similarly to the gate conductor, are collectively referred to herein as a gate “stack”. It will be appreciated that since all materials in the gate stack are typically similarly to each other, the distance by which the gate “stack” extends beyond a diffusion region boundary is approximately the same as the distance by which the gate conductor itself extends beyond the boundary. Thus to choose a single point of reference, the distances and sizes that are referred to herein are those of the gate conductor itself.

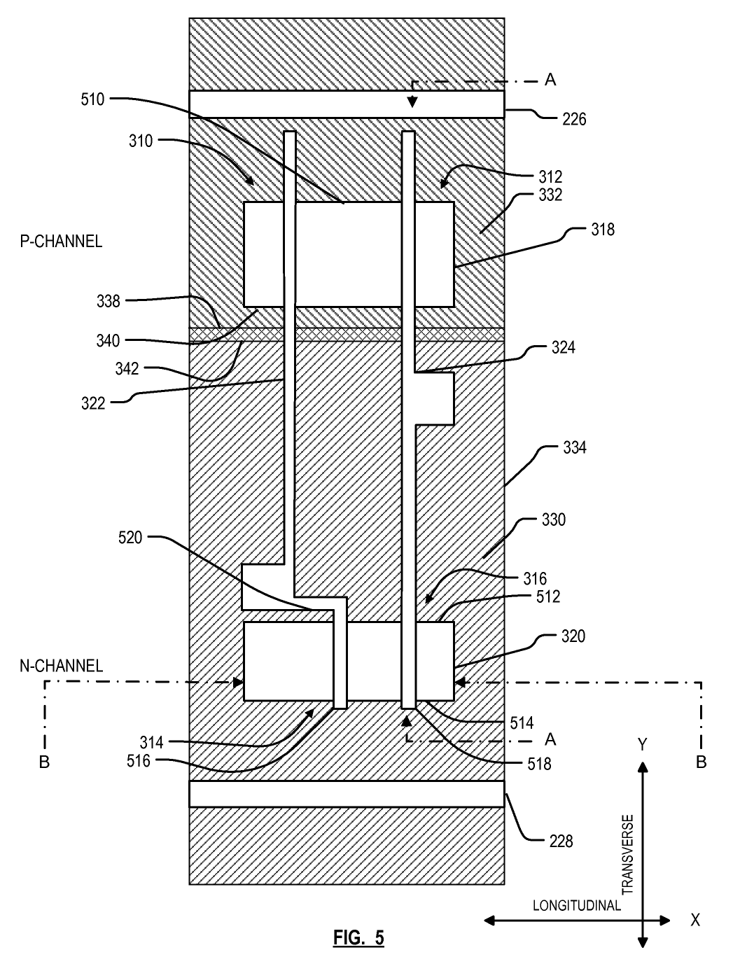

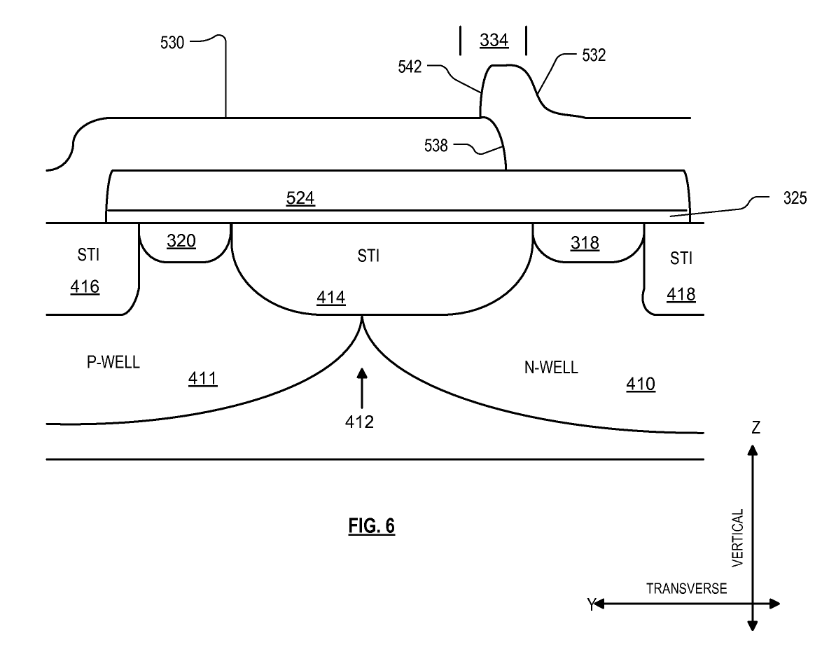

FIG. 5 is a plan view of a layout region implementing the same circuit portion as shown in FIG. 3, but modified to incorporate the above principles. FIG. 6 is a cross-sectional view of a portion of FIG. 5, taken along sight lines A-A of FIG. 5.

First, the edge interface between the tensile strained cap layer material 330 and the compressively strained cap layer material 332 has been repositioned much closer to the P-channel diffusion 318. The substantially coincident termination edges of the two cap layer materials preferably are located at a distance from the N-channel diffusion 320 which is between 0.75 and 1.0 times the distance to the P-channel diffusion region. Stated oppositely, the termination edges are located at a distance from the P-channel diffusion 318 which is between 0 and 0.25 times the distance to the N-channel diffusion region.

More preferably, the edge is located as close to the P-channel diffusion as possible, given manufacturing tolerances. The main limitation on how close the edge can be placed is the accuracy of the alignment stepper used during the fabrication process. More specifically, both the edge 340 of the P-channel diffusion 318 and the termination edge 338 of the tensile strained cap layer material 330 are defined using respective lithography masks. The two masks are used at different times during the fabrication process, and an alignment stepper is used for positioning the masks at exactly the same position laterally relative to the wafer for both steps. Steppers have become very accurate, but still carry some probability of misalignment. In particular, the probability that a given stepper will misalign a mask by a misalignment displacement x, is roughly Gaussian in x. Most steppers are delivered with their misalignment probability specified in terms of the standard deviation σ of this Gaussian distribution, but even if not, the specification can be determined empirically. Present day steppers have a σ equal to approximately 7 nm, but this is likely to shrink as steppers improve further in the future. Using σ as a metric, it is most preferable that the edge of the tensile strained cap material 330 be located at a distance from the P-channel diffusion region which is between 3 times σ and 5 times σ. This range of offsets is believed to position the edge 338 sufficiently close to the P-channel diffusion 318 to maximize the desirable transverse stress effects described above, while at the same time providing sufficient protection against overlap due to unintentional misalignment.

Second, the gate conductors 322 and 324 extend beyond the upper (in FIG. 5) edge 510 of the P-channel diffusion 318 by a much greater distance than typical or previously thought necessary. Since the extension portions of these gate conductors should not affect the circuit design, it is important that they do not overlap (in a plan view) any diffusion regions that are part of the circuit design, and it is important that they do not make electrical contact with any other conductive features of the integrated circuit design. Preferably the length in the transverse direction of the portion of the gate conductor extending beyond the edge 510 of the P-channel diffusion region 318 is at least half the distance from the first edge 510 to the nearest such diffusion region or conductive feature. In FIG. 5, the nearest such feature for both gate conductors 322 and 324 is the power supply conductor 226, and both gate conductors 322 and 324 extend more than half way to the power supply conductor 226. Also, in the embodiment of FIGS. 5 and 6 the compressively strained cap layer material 332 overlies the entire portion of the gate conductors 322 and 324 that extend beyond the P-channel diffusion region 318. In another embodiment, the compressively strained cap layer material can terminate short of the termination of the gate conductors, such that the gate conductors extend out even beyond the termination of the compressively strained cap layer material.

As with the position of cap layer edges 338 and 342, the main limitation on how close to a diffusion region or conductive feature the gate conductors can be made to terminate, is the probability of lithographic misalignment. Again using σ as a metric, it is most preferable that gate conductors crossing a P-channel diffusion should extend beyond the diffusion region boundary to a termination position that is between three times σ and five times σ short of the nearest diffusion region or conductive feature. This range of offsets from the nearest diffusion region or conductive feature is believed to be sufficiently far from the diffusion region boundary to maximize the tensile stress coupled into the P-channel transversely, while at the same time providing sufficient protection against affecting the circuit design due to unintentional misalignment.

Third, the gate conductors 322 and 324 extend beyond the upper (in FIG. 5) edge 512 and lower edge 514 of N-channel diffusion region 320 by as short a distance as practical before terminating (at positions 516 and 518) or turning (at position 520). (As used herein, the position at which a conductor “turns” is the position of the inside corner of the turn.) Again, as with the position of cap layer edges 338 and 342, the main limitation on how close the termination or turn can be made to the diffusion region boundary is the likelihood of lithographic misalignment. Again using σ as a metric, therefore, it is most preferable that gate conductors crossing an N-channel diffusion and extending transversely beyond the diffusion boundary, either terminate or turn at a distance that is no more than five times σ beyond the diffusion boundary. The distance of five times σ is believed to be sufficiently short so as to allow at least some beneficial transverse and vertical stress effects to be coupled into the N-channels, while also being sufficiently far to minimize the likelihood of detrimental effects due to unintentional misalignment. Alternatively, gate conductors crossing an N-channel diffusion and extending transversely beyond the diffusion boundary, should either terminate or turn at a distance that is no more than three times σ beyond the diffusion boundary.

It will be appreciated that the turning of a polysilicon gate conductor close to the nMOSFET is potentially risky due to possible shadowing of the tilted halo implant. This risk can be minimized by performing dual rotation halo implant instead of the conventional quad rotation. This remedy is possible for the 65 nm technology node and beyond because all polysilicon gates on the chip are parallel.

Note that the descriptions herein of the stress impact on transistors and of the methods to use stress to improve transistor performance apply to what are presently the standard crystallographic orientations used in the semiconductor industry, with the (100) wafer surface and <110> channel direction. The stress distribution changes only slightly for alternative possible crystal orientations of the wafer and the transistor channel, but the impact of stress on carrier mobility can change significantly not only in magnitude, but also in sign. Therefore, while some of the described techniques can be still applied to an arbitrary crystal orientation of the wafer and the transistors, they will need to be adapted for each specific case.

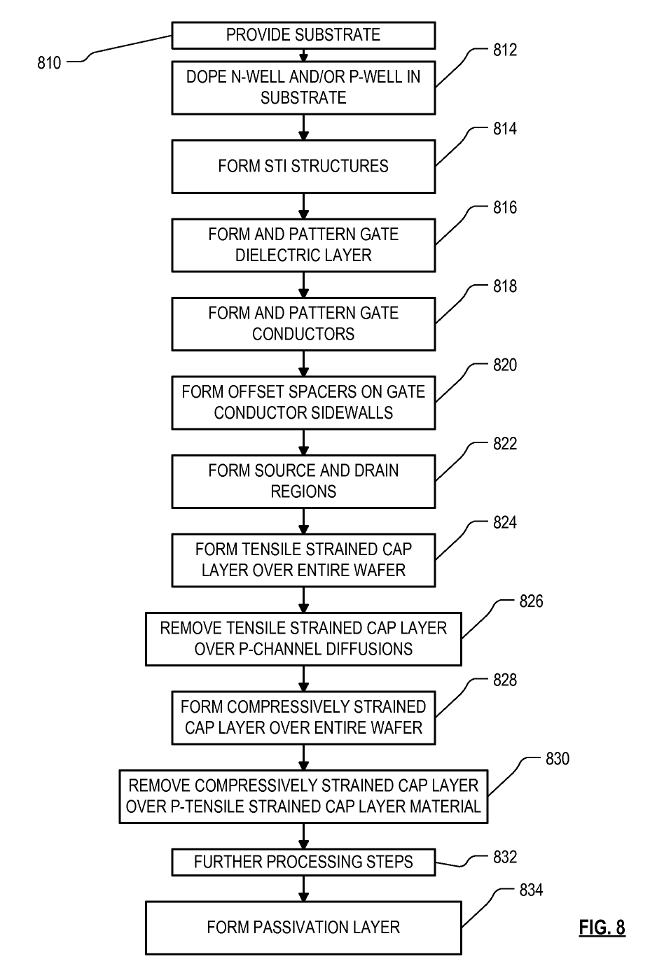

FIG. 8 is an overall flowchart of a typical integrated circuit fabrication process in which devices such as those of FIGS. 6 and 7 can be made. This flowchart is intended only for context, and is not intended to describe a complete fabrication process.

In step 810, a semiconductor substrate is provided. The substrate may include silicon, strained semiconductor, compound semiconductor, multi-layered semiconductors, or combinations thereof. For example, the substrate may include, silicon on insulator (SOI), stacked SOI (SSOI), stacked SiGe on insulator (S-SiGeOI), SiGeOI, and GeOI, or combinations thereof.

In step 812, the N-well 410 and/or the P-well 411 are formed in the substrate using well-known techniques. For example, they may be formed by a masking process followed by ion implantation and activation annealing.

In step 814, shallow trench isolation (STI) structures, e.g. 414, 416 and 418 in FIGS. 4 and 6, are formed. These may be formed for example by opening trenches in the substrate, forming a silicon nitride and/or silicon oxynitride liner in the trenches, and then backfilling the trenches with a thermal CVD deposited silicon oxide material.

In step 816, the gate dielectric layer is formed and patterned. For example, the gate dielectric layer may be formed of silicon oxide, silicon oxynitride, silicon nitride, nitrogen doped silicon oxide, high-K dielectrics, or combinations thereof. The high-K dielectrics may include metal oxides, metal silicates, metal nitrides, transition metal-oxides, transition metal silicates, metal aluminates, and transition metal nitrides, or combinations thereof. The gate dielectric portions may be formed using, for example, thermal oxidation, nitridation, sputter deposition, or chemical vapor deposition. The physical thickness of the gate dielectric layer may for example be in the range of 5 to 100 Angstroms.

In step 818, the gate conductors are formed and patterned. The gate conductors may be formed of, for example, one or more layers of doped polysilicon, polysilicon-germanium, metals, metal silicides, metal nitrides, or conductive metal oxides. After the gate conductor material is deposited over the entire wafer, the gate conductors (and other features using the same layer of material) may be patterned by first coating the wafer surface with photoresist, then exposing the photoresist through a mask. The exposed portions of photoresist are then washed away, leaving photoresist only over portions of the gate conductor layer that are to remain. The portions of the gate conductor layer not protected by photoresist are then etched away, and the unexposed photoresist it then also removed. The mask used to expose the photoresist in this step 818 is the mask in which gate conductors are extended beyond the boundaries of P-channel diffusion regions as far as practical, and gate conductors are terminated or turned as near as practical beyond the boundaries of N-channel diffusion regions.

In step 820, the offset spacers 720 (FIG. 7) are formed on the sidewalls of the gate conductors. These spacers may be formed of composite oxide/nitride materials by depositing one or more layers of silicon oxide, silicon nitride and/or silicon oxynitride, followed by wet or dry etching away portions of the one or more layers to form self-aligned offset spacers on either side of the gate structures. The offset spacers may include first forming an offset liner, e.g. an oxide, adjacent the gate structure to space a subsequently formed lightly doped drain region (e.g., by ion implantation) away from the gate structure.

In step 822, source and drain regions 710, 712 and 714 are formed in the substrate, for example by ion implantation following formation of the spacers. A protective oxide layer may be formed over the surface prior to an activation anneal of the source and drain regions and later removed prior to a salicide formation process.

In step 824, the tensile strained cap layer material 330 is applied over the entire wafer. The tensile stress should be as high as practical, because performance enhancement is proportional to stress. On the other hand, it should not be so high as to risk inducing crystal defects and therefore junction leakage. The tensile strained cap layer material may be silicon oxide, silicon nitride, silicon oxynitride, or combinations thereof, but is more preferably silicon nitride (e.g., SiN) and formed by a plasma enhanced CVD (PECVD) process.

In step 826, the tensile strained cap layer material 330 is removed over the P-channel diffusion regions 318. This may involve sub-steps of first coating the wafer surface with photoresist, then exposing the photoresist through a mask. It is this mask that defines the termination edge of the tensile strained cap layer material 330, as far as practical from the N-channel diffusions 320 and as close as practical to the P-channel diffusions 318. The exposed portions of photoresist are then washed away, leaving photoresist only over portions of the tensile strained cap layer material that are to remain. The portions of the tensile strained cap layer material not protected by photoresist are then etched away, and the unexposed photoresist it then also removed, leaving tensile strained cap layer material over the N-channel diffusions and extending transversely as close as practical to, but not over, the P-channel diffusions.

In step 828, the compressively strained cap layer material 332 is applied over the entire wafer. Again, the compressive stress should be as high as practical, but not so high as to risk inducing crystal defects and junction leakage. A stress of 2.5 GPa is reasonable. The material 332 may be silicon oxide, silicon nitride, silicon oxynitride, or combinations thereof, but is more preferably silicon nitride (e.g., SiN) and formed by a plasma enhanced CVD (PECVD) process similar to that by which cap layer material 330 was formed.

In step 830, the compressively strained cap layer material 332 is removed over the tensile strained cap layer material 330. As with the patterning of the tensile strained cap layer material 330, this may involve sub-steps of first coating the wafer surface with photoresist, then exposing the photoresist through a mask, then washing away the exposed portions of the photoresist, and then etching away the portions of the compressively strained cap layer material not protected by photoresist. The unexposed photoresist is then also removed, leaving compressively strained cap layer material over the P-channel diffusions and extending by as small a distance as practical transversely beyond the P-channel diffusion boundaries toward the N-channel diffusions. As previously mentioned, the edge 342 of the compressively strained cap layer material 332 preferably coincides with the edge 338 of the tensile strained cap layer material 330, but this is not critical for purposes of the inventive aspects described herein.

In step 832, the wafer undergoes further processing steps known in the art or yet to be developed, such as formation of additional layers of conductive material, and formation of dielectric via layers between them. Finally, in step 834, a passivation layer is formed above the other layers in order to protect the circuitry from contamination during assembly. Silicon nitride and/or silicon dioxide may be used for this purpose. A final mask and passivation etch removes the passivation material from the bonding pads so that bonding wires can be connected.

The steps of exposing photoresist through a mask, in steps 818, 826 and 830, among others, involves use of a stepper. The stepper operates by first loading the wafer from a cassette, onto a wafer stage where it is aligned in a known manner to the stage. A loader loads the particular mask (also called a reticle) onto a reticle stage, where it is aligned to the wafer. Since the same reticle can be used to expose many wafers, it is loaded once before a series of wafers is exposed, and is realigned periodically. Once the wafer and reticle are aligned, the wafer stage, which is moved in X and Y directions by worm screws or linear motors, moves the wafer into position so that the first of the many patterns to be exposed on it is located directly under the reticle. Although the wafer is aligned after it is placed on the wafer stage, each exposure is aligned again using alignment marks located in the pattern for each final IC chip. Once this fine alignment is completed, the illumination system passes light through the reticle, through a reduction lens, and on to the surface of the wafer. As mentioned, the stepper has a misalignment probability in each of the X and Y directions that is roughly Gaussian in shape, and the standard distribution σ of the Gaussian curve is either provided as part of the specifications for the stepper system or determined empirically.

The concepts described herein for taking best advantage of transverse and vertical stress coupled into transistor channels from strained cap layers, also can be viewed as a set of masks that incorporate one or more of such concepts. They can also be viewed as a method of laying out a circuit design, so as to incorporate one or more of such concepts. The method of laying out a circuit design can be performed manually in one embodiment, automatically in another embodiment, and partially automatically and partially manually in a third embodiment. When performed automatically, at least the concepts that involve the length by which a gate conductor extends beyond a diffusion region can be incorporated into the logic of place-and-route software.

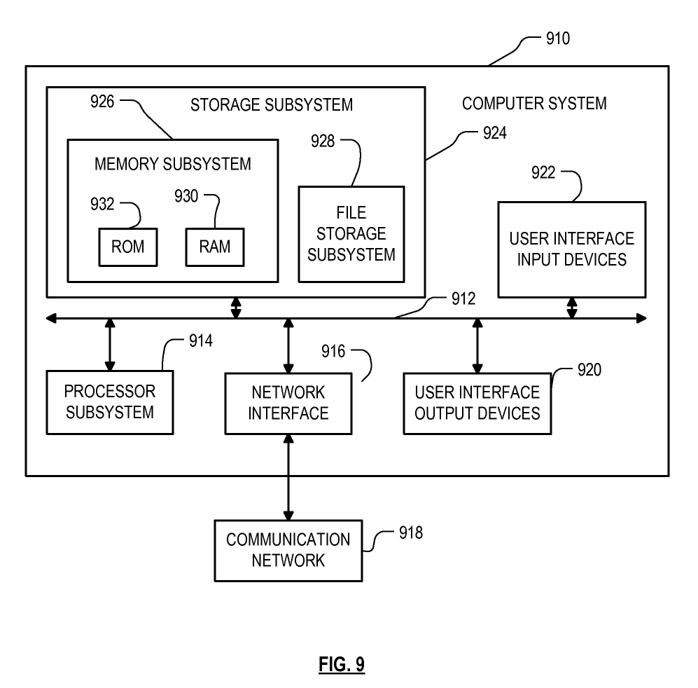

FIG. 9 is a simplified block diagram of a computer system 910 that can be used to implement place-and-route software incorporating aspects of the present invention. Computer system 910 typically includes a processor subsystem 914 which communicates with a number of peripheral devices via bus subsystem 912. These peripheral devices may include a storage subsystem 924, comprising a memory subsystem 926 and a file storage subsystem 928, user interface input devices 922, user interface output devices 920, and a network interface subsystem 916. The input and output devices allow user interaction with computer system 910. Network interface subsystem 916 provides an interface to outside networks, including an interface to communication network 918, and is coupled via communication network 918 to corresponding interface devices in other computer systems. Communication network 918 may comprise many interconnected computer systems and communication links. These communication links may be wireline links, optical links, wireless links, or any other mechanisms for communication of information. While in one embodiment, communication network 918 is the Internet, in other embodiments, communication network 918 may be any suitable computer network.

The physical hardware component of network interfaces are sometimes referred to as network interface cards (NICs), although they need not be in the form of cards: for instance they could be in the form of integrated circuits (ICs) and connectors fitted directly onto a motherboard, or in the form of macrocells fabricated on a single integrated circuit chip with other components of the computer system.

User interface input devices 922 may include a keyboard, pointing devices such as a mouse, trackball, touchpad, or graphics tablet, a scanner, a touch screen incorporated into the display, audio input devices such as voice recognition systems, microphones, and other types of input devices. In general, use of the term “input device” is intended to include all possible types of devices and ways to input information into computer system 910 or onto computer network 918.

User interface output devices 920 may include a display subsystem, a printer, a fax machine, or non-visual displays such as audio output devices. The display subsystem may include a cathode ray tube (CRT), a flat-panel device such as a liquid crystal display (LCD), a projection device, or some other mechanism for creating a visible image. The display subsystem may also provide non-visual display such as via audio output devices. In general, use of the term “output device” is intended to include all possible types of devices and ways to output information from computer system 910 to the user or to another machine or computer system.

Storage subsystem 924 stores the basic programming and data constructs that provide the functionality of certain embodiments of the present invention. For example, the various modules implementing the functionality of certain embodiments of the invention may be stored in storage subsystem 924. These software modules are generally executed by processor subsystem 914.

Memory subsystem 926 typically includes a number of memories including a main random access memory (RAM) 930 for storage of instructions and data during program execution and a read only memory (ROM) 932 in which fixed instructions are stored. File storage subsystem 928 provides persistent storage for program and data files, and may include a hard disk drive, a floppy disk drive along with associated removable media, a CD-ROM drive, an optical drive, or removable media cartridges. The databases and modules implementing the functionality of certain embodiments of the invention may be stored by file storage subsystem 928. The host memory 926 contains, among other things, computer instructions which, when executed by the processor subsystem 914, cause the computer system to operate or perform functions as described herein. As used herein, processes and software that are said to run in or on “the host” or “the computer”, execute on the processor subsystem 914 in response to computer instructions and data in the host memory subsystem 926 including any other local or remote storage for such instructions and data.

Bus subsystem 912 provides a mechanism for letting the various components and subsystems of computer system 910 communicate with each other as intended. Although bus subsystem 912 is shown schematically as a single bus, alternative embodiments of the bus subsystem may use multiple busses.

Computer system 910 itself can be of varying types including a personal computer, a portable computer, a workstation, a computer terminal, a network computer, a television, a mainframe, or any other data processing system or user device. Due to the ever-changing nature of computers and networks, the description of computer system 910 depicted in FIG. 9 is intended only as a specific example for purposes of illustrating the preferred embodiments of the present invention. Many other configurations of computer system 910 are possible having more or less components than the computer system depicted in FIG. 9.

The foregoing description of preferred embodiments of the present invention has been provided for the purposes of illustration and description. It is not intended to be exhaustive or to limit the invention to the precise forms disclosed. Obviously, many modifications and variations will be apparent to practitioners skilled in this art. In particular, and without limitation, any and all variations described, suggested or incorporated by reference in the Background section of this patent application are specifically incorporated by reference into the description herein of embodiments of the invention. The embodiments described herein were chosen and described in order to best explain the principles of the invention and its practical application, thereby enabling others skilled in the art to understand the invention for various embodiments and with various modifications as are suited to the particular use contemplated. It is intended that the scope of the invention be defined by the following claims and their equivalents.

1. A method for making an integrated circuit device implementing at least a portion of an integrated circuit design, comprising:
providing a substrate carrying a P-channel diffusion region;
forming a gate conductor crossing the P-channel diffusion region transversely and terminating beyond a first edge of the P-channel diffusion region, the portion of the gate conductor extending beyond the first edge of the P-channel diffusion region making no electrical contact with any other features of the integrated circuit design, and overlying no other diffusion regions;
forming a compressively strained cap material overlying at least a portion of the gate conductor; and
forming an additional feature carried by the substrate and spaced transversely from the P-channel diffusion region and in-line with the gate conductor, the additional feature being a member of the group consisting of (1) an additional diffusion region forming part of the integrated circuit design, and (2) an additional feature in the same layer as the gate conductor,
wherein the length in the transverse direction of the portion of the gate conductor extending beyond the first edge of the P-channel diffusion region is at least half the distance from the first edge of the P-channel diffusion region to the additional feature.

2. A method according to claim 1, wherein the overlap of the gate conductor and the P-channel diffusion region defines a channel region,
and wherein the compressively strained cap material terminates at an edge that is located beyond termination of the gate conductor transversely from the channel region.

3. A method for laying out at least a portion of an integrated circuit device, for use in a fabrication process in which a compressively strained cap material will overly at least a portion of a P-channel diffusion region, comprising the steps of:
laying out the P-channel diffusion region; and
laying out a gate conductor crossing the P-channel diffusion region transversely and terminating in the layout beyond a first edge of the P-channel diffusion region, the portion of the gate conductor extending beyond the first edge of the P-channel diffusion region in the layout making no electrical contact with any other features of the integrated circuit design, and overlying no other diffusion regions; and
laying out an additional feature spaced transversely from the P-channel diffusion region and in-line with the gate conductor, the additional feature being a member of the group consisting of (1) an additional diffusion region forming part of the integrated circuit design, and (2) an additional feature in the same layer as the gate conductor,
wherein in the layout, the length in the transverse direction of the portion of the gate conductor extending beyond the first edge of the P-channel diffusion region is at least half the distance from the first edge of the P-channel diffusion region to the additional feature.

4. A method according to claim 3, wherein the overlap of the gate conductor and the P-channel diffusion region defines a channel region,
and wherein the compressively strained cap material terminates in the layout at an edge that is located beyond termination of the gate conductor transversely from the channel region.

5. A method according to claim 3, for use during fabrication with a wafer stepper having a misalignment probability distribution with a standard deviation of σ,
wherein the gate conductor terminates in the layout at a position that is between three times σ and five times σ short of the additional feature.

6. A method for making an integrated circuit device, comprising the steps of:
providing a substrate;
forming an N-channel diffusion region carried by the substrate, using a first lithography mask positioned relative to the substrate by a wafer stepper having a misalignment probability distribution with a standard deviation of σ;
using a third lithography mask positioned relative to the substrate by the wafer stepper, forming a gate conductor crossing the N-channel diffusion region and extending transversely beyond a first edge of the N-channel diffusion region, the third lithography mask defining the gate conductor so as to terminate or turn at a first distance that is no more than five times σ beyond the first edge of the N-channel diffusion region; and
forming a tensile strained cap material overlying at least a portion of the gate conductor and extending transversely beyond the first edge of the N-channel diffusion region.

7. A method according to claim 6, wherein the gate conductor terminates at the first distance.

8. A method according to claim 6, wherein the gate conductor turns by 90 degrees at the first distance.

9. A method according to claim 6, wherein the first distance is between three times σ and five times σ.

10. A method according to claim 6, wherein the tensile strained cap material extends transversely beyond the first distance.

11. A method for laying out at least a portion of an integrated circuit device, for use in a fabrication process in which a tensile strained cap material will overly an N-channel diffusion region, for use during fabrication with a wafer stepper having a misalignment probability distribution with a standard deviation of σ, comprising the steps of:
laying out the N-channel diffusion region; and
laying out a gate conductor crossing the N-channel diffusion region and extending transversely beyond a first edge of the N-channel diffusion region, the gate conductor terminating or turning at a first distance that is no more than five times σ beyond the first edge of the N-channel diffusion region.

12. A method according to claim 11, wherein the gate conductor terminates in the layout at the first distance.

13. A method according to claim 11, wherein the gate conductor turns by 90 degrees at the first distance in the layout.

14. A method according to claim 11, wherein the first distance is between three times σ and five times σ.

15. A method according to claim 11, wherein the tensile strained cap material extends transversely in the layout beyond the first distance.
